(19) United States
(12) Patent Application Publication
(10) Pub. No.: US 2011/0133726 A1
(43) Pub. Date: Jun. 9, 2011

(54) Precision alignment system

(76) Inventors: Alexander Ballantyne, Edinburgh (GB); Mark Rhodes, West Lothian (GB); Brendan Peter Hyland, Edinburgh (GB); Brian Kearns, Dublin (IE)

(21) Appl. No.: 12/634,481

(22) Filed: Dec. 9, 2009

(51) Int. Cl. G01B 7/14; G01R 33/00

(52) U.S. Cl. 324/207.11

(57) ABSTRACT

The present invention provides a precision alignment system operable to provide alignment of a first and second apparatus. The precision alignment system makes use of inductive coupling between loop antennas in the first and second apparatus. The mechanism for alignment is the detection of a null in the signal induced in the loop antennas of the second apparatus arising from an input signal fed to a loop antenna of the first apparatus. The precision alignment system can be incorporated in a system for the wireless transfer of electrical power or may be incorporated in a system for the transfer of data. The precision alignment system of the present invention is particularly suited to applications where optical or other means for alignment of two apparatus are unreliable. In particular, the alignment system disclosed is suitable for operation underwater.

### CROSS-REFERENCE TO RELATED APPLICATIONS

This application is related to commonly owned U.S. Ser. No. ______, filed concurrent with this application, identified as Attorney Docket No. WIR 0033, and entitled “Transmit and Receive Antenna”, which application is fully incorporated herein by reference.

### FIELD OF USE

The present invention relates to the technical problem of providing a system for the precision alignment of a first apparatus with a second apparatus.

### DESCRIPTION OF THE RELATED ART

Alignment systems are used in a wide range of applications including, device fabrication, targeting, printing, data transfer, power transfer, mechanical machining, robotics etc.

An extremely common and rudimentary system for alignment of a first and a second apparatus is based on providing a pair of mechanical interfaces, where one interface is the inverse of the other, so that one apparatus fits into the other only when correct alignment is achieved.

For automatic systems, alignment is often achieved by an optical system; for example, by the provision of a photodiode in a first apparatus and a light emitting diode in a second apparatus, and where alignment is defined by the position of the second apparatus relative to the first apparatus when a focused beam of the light emitting diode falls on the photodiode.

Systems for alignment of an apparatus by optical means are taught in U.S. Pat. No. 4,243,877 “Electro-optical Target for an Optical Alignment System” Cruz, and U.S. Pat. No. 7,312,870 “Optical Alignment Detection System”; Fritz et al.

Alignment systems based on optical devices etc can provide an extremely precise alignment of one apparatus to another apparatus. However, in a range of environments, optical systems cannot feasibly be employed.

In particular, for underwater applications, optical systems are prone to failure. Underwater installations, suffer from poor visibility due to turbidity which severely limits the range of optical systems. Furthermore, underwater systems are affected by the growth of algae and are also affected by a gradual deposition of sediment; both of these phenomena progressively block optical beams over a period of time and thus limit the viability of optical alignment systems for use underwater.

A system for alignment of a first apparatus with a second apparatus based on magnetic elements is taught by Fullerton et al in United States Patent Application Publication 2009/0251244, “System and Method for Alignment of Objects”; and similarly in United States Patent Application Publication 2009/0251263, “System and Method for Configuring a Plurality of Magnets”.

A combined system providing alignment by means of magnetic devices, and inductive power transfer from a base unit to a portable unit is taught in PCT International Patent Application Publication WO2009/116025; “Inductive Transmission System” Azancot et al.

In general, magnetic and inductive alignment systems do not provide the high level of precision of optical systems, and are suitable for use only in applications where a rough alignment is sufficient.

Moreover, magnetic and inductive systems do not provide an alignment mechanism whereby a first and second apparatus can be aligned from a starting position where both apparatus are grossly misaligned. To provide this feature, a secondary mechanism is required which provides a gradual lead in of one apparatus to the other.

Electromagnetic signals in the radio section of the spectrum can be used for the alignment of one apparatus to another. Electromagnetic signals propagate underwater, and do not require a direct path from transmitter to receiver. However, radio signals are rapidly attenuated with distance underwater. This limitation can be overcome by the adoption of very low frequency signals—for example in the frequency range from 10 Hz to 10 MHz. However, a problem which prevents the use of low frequency electromagnetic signals for alignment of one apparatus to another is that the wavelength increases as the frequency decreases, thus a system based on a focused low frequency radio signal is only capable of providing poor resolution of alignment of one apparatus to another.

There are a range of underwater applications where a precision alignment system would be highly desirable. The manual alignment of a first apparatus to a second apparatus in an underwater environment is a complex task to accomplish; typically, manual alignment of a pair of apparatus is achieved using a Remotely Operated Vehicle (ROV) or an Autonomous Underwater Vehicle (AUV). Even for manual alignment, a system that provides feedback regarding the degree of alignment would render the process substantially more efficient. Underwater applications which would benefit from a precision alignment system include: the alignment of male and female connectors which provide an electrical connection, the alignment of male and female connectors which provide a mechanical coupling, the alignment of devices which are operable at the connection of oil and gas pipelines, the alignment of a transmitter antenna and a receiver antenna for a wireless communications system that provides high speed data transfer.

A specific application for an underwater alignment system is the precise alignment of primary and secondary sections of a wireless power transfer system. Wireless power transfer systems are taught in PCT International Patent Application Publication WO 2007/086753; “A Hotstab Device for Use Underwater”; Hodnefjell. The essential features of a wireless power transfer system such as that taught by Hodnefjell, are primary and secondary coils which are formed around first and second cores of high magnetic permeability. When opposing faces of the first and second cores are brought into close proximity with each other, the combined system of the first and second cores behaves in a similar manner to a single core; thus, highly efficient power transfer can take place between the primary and secondary coils. However, to achieve this efficient power transfer between the primary and secondary coils, it is essential that the first a and second cores are aligned to a high level of precision. In practice, this can be an extremely difficult task to achieve in an underwater environment.

### SUMMARY OF THE INVENTION

According to a first aspect, the present invention provides a system for aligning a first apparatus and a second apparatus.

The alignment system of the present invention is capable of providing alignment to a high level of precision.

The alignment system of the present invention provides comparable precision to an optical alignment system, but is not restricted by a requirement for a direct un-obscured path for observation of the alignment devices of the two systems.

The alignment system of the present invention provides a means to track the alignment of a first apparatus to a second apparatus from a starting point where both apparatus are grossly misaligned.

The alignment system of the present invention is capable of providing both lateral/horizontal alignment and axial/vertical alignment of the first and second apparatus.

A further object of the present invention is to provide a precision alignment system suitable for operation in an underwater environment.

Another object of the present invention is to provide an alignment system further comprising a means for wireless data transfer between the first and the second apparatus or vice versa.

The following convention is adopted herein: an adjustment that brings faces of the first apparatus and the second apparatus closer together or further apart is referred to as an axial Z adjustment; an adjustment that moves a face of the first apparatus parallel to a face of the second apparatus is referred to as a lateral XY adjustment.

The precision alignment system of the present invention comprises a first apparatus and a second apparatus, the first apparatus comprising a magnetic loop antenna, and the second apparatus comprising at least a first receiving antenna, which receives electromagnetic and/or inductive signals transmitted by the loop antenna. The receiving antennas of the present invention are hereinafter referred to as RX antennas.

Preferably, the lateral XY dimensions of the magnetic loop antenna are greater than the axial Z dimension thereof.

In some embodiments, the first and/or second RX antenna is a loop antenna having lateral XY dimensions which are greater than respective axial Z dimensions thereof.

In alternative embodiments, the first and/or second RX antenna is a solenoid having an axial Z dimension which is greater than lateral XY dimensions thereof. For improved sensitivity, the solenoid antenna may be formed on a core of a material having a large magnetic permeability.

During use, an input electrical signal is fed from the first apparatus to the magnetic loop antenna producing a magnetic field in the surrounding region. When the second apparatus is within a range of the first apparatus, the magnetic field surrounding the magnetic loop antenna induces a first induced electrical signal in the first RX antenna. The first induced signal varies with position of the first RX antenna relative to the magnetic loop antenna.

At a specific XY offset of the centre axis of the first RX antenna relative to the centre axis of the magnetic loop antenna, the magnitude of the first induced electrical signal decreases to a minimum, substantially zero value. Consequently, optimum alignment of the second apparatus can be defined by the position of the first RX antenna when the magnitude of the first induced signal is at a local minimum, substantially zero value.

The local minimum in the first induced signal occurs at a precise repeatable XY offset distance of the first RX antenna from the magnetic loop antenna thereby providing a mechanism for the precise alignment of the second apparatus to the first apparatus.

As the XY offset of the centre axis of the first RX antenna relative to the centre axis of the magnetic loop antenna is increased beyond the null offset distance, the magnitude of the first induced signal in the first RX antenna increases rapidly to a local maximum. Thereafter, the magnitude of the first induced signal falls off gradually as the first RX antenna is offset further and further from the magnetic loop antenna. The gradual fall-off in the magnitude of the first induced signal with increasing distance provides a mechanism for guiding the second apparatus to the first apparatus from a starting position of gross misalignment.

In some embodiments, the second apparatus further comprises a second RX antenna so that when the second apparatus is within a range of the first apparatus, the electrical signal in the magnetic loop antenna induces first and second induced electrical signals in the first and second RX antennas.

In this way the XY position of the second apparatus relative to the first apparatus can be determined uniquely by the position of the second apparatus when the magnitude of the first and second induced signals are both at local minima. Moreover, precision alignment can be achieved and a mechanism for guiding the second apparatus to the first apparatus from a starting position of gross misalignment is provided.

For alignment systems where rotational orientation is not important (E.G co-axial connections etc) the magnetic loop antenna may be circular. However, for alignment systems where both positional alignment of a single point and rotational alignment are required an alternative shape of the magnetic loop antenna is preferable. For such applications, the magnetic loop antenna may be chosen to have an extended dimension in the Y-direction, and a reduced dimension in the X-direction—an ellipse being an example of a shape which meets these criteria. Careful positioning of the first and second RX antennas in the second apparatus provides a system that can achieve lateral XY alignment of a point on the second apparatus relative to a point on the first apparatus, and moreover which can achieve a pre-defined angular alignment of the second apparatus.

The precision alignment system of the present invention is operable to provide axial z alignment of the first apparatus to the second apparatus based on the measured sharpness of the null in the first induced signal and/or the sharpness of the null in the second induced signal.

In another embodiment, the first apparatus further comprises a primary inductive device, which is substantially co-axial with the magnetic loop antenna and the second apparatus further comprises a secondary inductive device. The first apparatus is arranged so that when the second apparatus is optimally aligned according to the system of the present invention, the primary and secondary inductive devices are precisely aligned. This arrangement provides the optimum configuration of the first apparatus and the second apparatus for the wireless transfer of electrical power from the primary inductive device of the first apparatus to the secondary inductive device of the second apparatus or vice versa.

In another embodiment, the second apparatus further comprises a secondary antenna. The first apparatus is arranged so that when the second apparatus is optimally aligned according to the system of the present invention, the secondary antenna is positioned so that it is precisely co-axial with the magnetic loop antenna of the first apparatus. This arrangement provides an optimum configuration of the magnetic loop antenna of the first apparatus and the secondary antenna of the second apparatus for high speed wireless transfer of data from the first apparatus to the second apparatus.

In a further embodiment, the first and second apparatus both comprise secondary antennas which are precisely aligned when the first and second apparatus are aligned according to the system of the present invention. This arrangement provides an optimum configuration of secondary antennas of the first and second apparatus for high speed wireless transfer of data from the first apparatus to the second apparatus, or vice versa. For example, this embodiment is particularly suited to the wireless transmission and reception of high bandwidth video images.

In yet another embodiment, the second apparatus comprises a first group of three or more closely spaced RX loop antennas and a second group of three or more closely spaced RX loop antennas. This embodiment provides a mechanism for determining the fine adjustment required when the first apparatus has been approximately aligned to the second apparatus.

Preferably, the input electrical signal fed to the magnetic loop antenna of the first apparatus is in the frequency range extending from 10 Hz to 100 MHz.

In some embodiments, the alignment system of the present invention is activated when the second apparatus is within a short range of the first apparatus. Activation may be provided by the transmission of a signal by the second apparatus, which is received by the first apparatus.

In typical embodiments, the first apparatus of the alignment system of the present invention is a base station, and the second apparatus is a mobile unit. Alternatively, the first apparatus may be a mobile unit, and the second apparatus may have a fixed position.

The alignment system of the present invention is particularly suited to underwater systems. In particular, the alignment system of the present invention is particularly suited to environments where alignment systems based on optical means are prone to failure.

According to a second aspect of the present invention, there is provided precision alignment method comprising the steps of transmitting an electromagnetic signal via a magnetic loop antenna of a first apparatus, receiving the transmitted electromagnetic signal as a first induced electrical signal in a first RX antenna of a second apparatus, determining the magnitude of the first induced electrical signal, adjusting the position of the second apparatus, monitoring the change in the first induced electrical signal and achieving alignment of the second apparatus relative to the first apparatus when the magnitude of said first induced electrical signal falls to zero.

The precision alignment method may further include the step of receiving the transmitted electromagnetic signal as a second induced signal in a second RX antenna of the second apparatus, where the change in the second induced electrical signal is also monitored on adjustment of the position of the second apparatus and where alignment of the second apparatus relative to the first apparatus is achieved when the magnitude of both the first induced electrical signal and the second induced electrical signal falls to zero

Embodiments of the present invention will now be described with reference to the accompanying figures in which:

### BRIEF DESCRIPTION OF DRAWINGS

FIG. 1 shows a diagram illustrating a precision alignment system according to a first embodiment of the present invention.

FIG. 2 shows a diagram illustrating an alignment and power transfer system according to a second embodiment of the present invention.

FIG. 3 shows a diagram illustrating a system of first and second overlapping loop antennas where the net magnetic flux generated by the first loop antenna and intersecting the plane of the second loop antenna is zero.

FIG. 4 shows a diagram of the magnetic field strength with distance from the centre of a loop antenna.

FIG. 5 shows a diagram illustrating the experimentally measured power transferred from one loop antenna to another as a function of the separation of their respective centers.

FIG. 6 shows a diagram illustrating angular misalignment of the first and second apparatus of FIG. 1.

FIG. 7 shows a diagram illustrating a precision alignment system according to a third embodiment of the present invention comprising mechanical connectors which are precisely aligned by means of the present invention.

FIG. 8 shows a diagram illustrating a precision alignment system according to a fourth embodiment of the present invention.

FIG. 9 shows a diagram illustrating a precision alignment system according to a fifth embodiment of the present invention.

### DETAILED DESCRIPTION

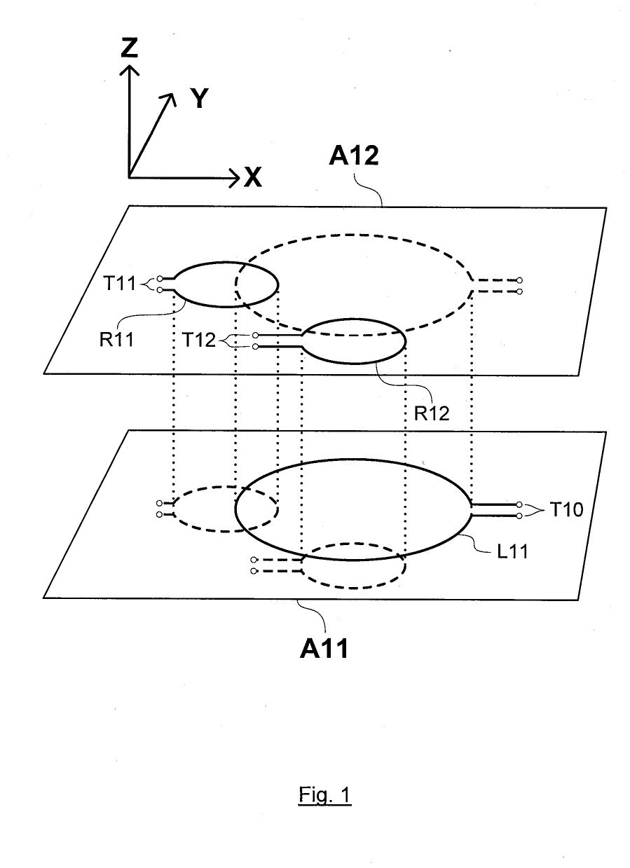

FIG. 1 shows a diagram illustrating a precision alignment system according to a first embodiment of the present invention. The alignment system comprises first apparatus A11 and second apparatus A12. First apparatus A11 comprises magnetic loop antenna L11 with an input/output (I/O) terminal T10. Second apparatus A12 comprises first RX loop antenna R11 and second RX loop antenna R12. First RX loop antenna R11 comprises I/O terminal T11 and second RX loop antenna R12 similarly comprises I/O terminal T12. For this particular embodiment, magnetic loop antenna L11, first RX loop antenna R11 and second RX loop antenna R12 are all circular. However, the present invention is by no means limited to embodiments comprising circular loop antennas.

In FIG. 1, the lateral XY positions of first and second RX loop antennas R11 and R12 relative to magnetic loop antenna L11 are shown by dotted lines projected on a plane of first apparatus A11. Similarly, the lateral XY position of magnetic loop antenna L11 relative to first and second RX loop antennas R11 and R12 is shown as a dotted line projected on a plane of second apparatus A12. In FIG. 1, the centre of first RX loop antenna R11 is offset in a lateral XY direction relative to the centre of magnetic loop antenna L11; similarly, the centre of second RX loop antenna R12 is offset in a lateral XY direction relative to the centre of magnetic loop antenna L11.

During use, an alternating signal voltage is fed to I/O terminal T10 of magnetic loop antenna L11. The alternating voltage across I/O terminal T10 produces an alternating current in magnetic loop antenna L11, the alternating current in magnetic loop antenna L11 produces a time varying magnetic field in the surrounding region. This time varying magnetic field induces an electromotive force (emf) at I/O terminals T11 of first RX loop antenna R11 and at I/O terminals T12 of second RX loop antenna R12.

For a given XY offset of the centre of first RX loop antenna R11 relative to magnetic loop antenna L11, a portion of the magnetic flux generated by magnetic loop antenna L11 and perpendicular to the plane of first RX loop antenna R11 has one direction, and the other portion thereof has an opposite direction. Consequently, there is a specific lateral XY offset of first RX loop antenna R11 relative to magnetic loop antenna L11 where both portions cancel, thereby producing a net zero magnetic flux intersecting the plane of first RX loop antenna R11. At this position, no emf is induced at I/O terminal T11 of first RX loop antenna R11. The position of first RX loop antenna R11 relative to magnetic loop antenna L11 where there is a null in the induced emf at I/O terminal T11 is referred to hereinafter as the null offset distance of first RX loop antenna R11.

As the lateral XY offset of first RX loop antenna R11 relative to magnetic loop antenna L11 is increased beyond the null offset distance, the magnitude of the induced emf at terminal T11 of first RX loop antenna R11 increases rapidly to a local maximum value. As the lateral XY offset of first RX loop antenna R11 relative to magnetic loop antenna L11 is increased further again, the magnitude of the induced emf at terminal T11 of first RX loop antenna R11 falls off, gradually decaying to a value of zero. The gradual fall-off in the induced emf in first RX loop antenna R11 as the offset is increased well beyond the null offset distance provides a means for a gradual lead in during alignment of second apparatus A12 to first apparatus A11 starting from a position where second apparatus A12 is grossly misaligned.

Similarly, for a given lateral XY offset of second RX loop antenna R12 relative to magnetic loop antenna L11, a portion of the magnetic flux generated by magnetic loop antenna L11 and perpendicular to the plane of second RX loop antenna R12 has one direction, and the other portion thereof has an opposite direction. Consequently, there is a single unique position of second RX loop antenna R12 relative to magnetic loop antenna L11 where both portions cancel thereby producing a net zero magnetic flux intersecting the plane of second RX loop antenna R12. At this position, no emf is induced at I/O terminal T12 of second RX loop antenna R12. The position of second RX loop antenna R12 relative to magnetic loop antenna L11 where there is a null in the induced emf at I/O terminal T12 is referred to hereinafter as the null offset distance of second RX loop antenna.

When a null in the emf is simultaneously measured at terminal T11 of first RX loop antenna R11 and terminal T12 of second RX loop antenna R12, second apparatus A12 is located at the unique position defined by the null offset distance of first RX loop antenna R11 and the null offset distance of second RX loop antenna R12. Thus, second apparatus A12 can be aligned precisely and uniquely according to the measurement of a null in the induced emf at I/O terminal T11 of first RX loop antenna R11 and a null in the induced emf at I/O terminal T12 of second RX loop antenna R12.

The alignment system of FIG. 1 of the present invention is capable of providing alignment of a first and second apparatus to a precision of millimeters.

For the specific case where each of magnetic loop antenna L11, first RX loop antenna R11 and second RX loop antennas R12 is circular, the condition for a simultaneous null in the first induced emf at terminal T11 and the second induced emf at terminal T12 is rotationally symmetric about the centre of magnetic loop antenna L11.

For alignment systems where both positional alignment of a single point and rotational alignment are required, an alternative shape of magnetic loop antenna L11 is preferable. For such applications, magnetic loop antenna L11 may be chosen to have an extended dimension in the Y-direction, and a reduced dimension in the X-direction.

As the axial Z displacement of the second apparatus from the first apparatus decreases, the sharpness of the null in the induced emf at I/O terminal T11 and I/O terminal T12 increases. Thus, as second apparatus A12 gets closer to first apparatus A11 the precision of the alignment increases.

A measure of the axial Z alignment of the second apparatus relative to the first apparatus can be provided by means of the sharpness of the null in the induced emf at I/O terminal T11 and I/O terminal T12.

The alignment system of a first embodiment of the present invention depicted in FIG. 1 may be activated when the second apparatus is within a short range of the first apparatus. Activation may be provided by the transmission of a signal by the second apparatus, which is received by the first apparatus.

For the specific case where each of magnetic loop antenna L11, first RX loop antenna R11 and second RX loop antenna R12 is circular, each having the same radius, the centre to centre distance D of first RX loop antenna R11 and second RX loop antenna relative to magnetic loop antenna L11 which produces a null in the respective induced emf at T11 and T12 is given by the following equation:

D=1.52×R

where R is the radius of magnetic loop antenna L11, first RX loop antenna R11 and second RX loop antenna R1.

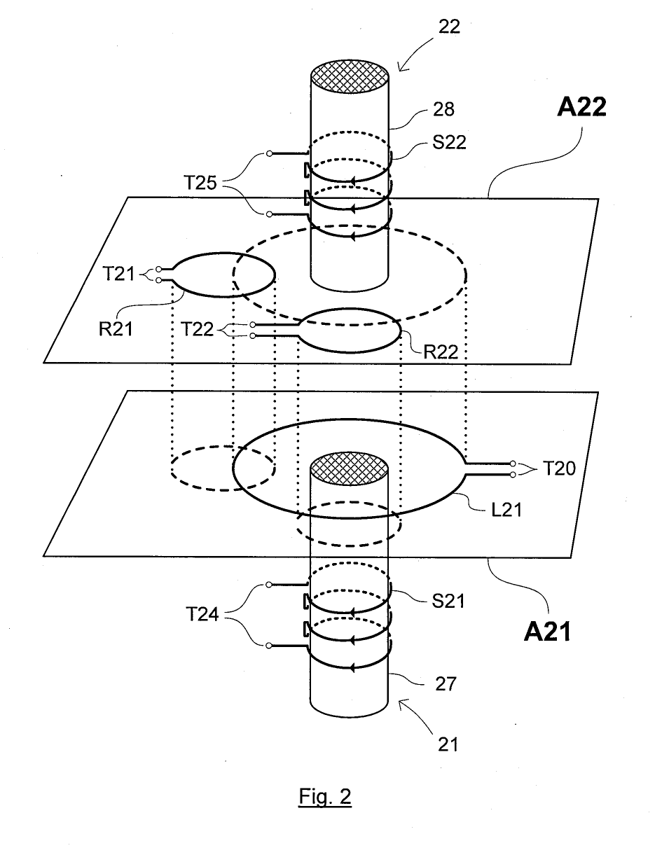

FIG. 2 shows a diagram illustrating an alignment and power transfer system according to a second embodiment of the present invention. The alignment and power transfer system comprises first apparatus A21 and second apparatus A22. First apparatus A21 comprises magnetic loop antenna L21 with an I/O terminal T20, and further comprises power inductor 21. Power inductor 21 comprises solenoid S21, magnetic core 27 and I/O terminal T24. Second apparatus A22 comprises first RX loop antenna R21 and second RX loop antenna R22 where first RX loop antenna R21 comprises I/O terminal T21 and second RX loop antenna R22 similarly comprises I/O terminal T22. Second apparatus A22 further comprises power inductor 22 separately comprising solenoid S22, magnetic core 28 and I/O terminal T25.

During use, the alignment and power transfer system of an embodiment of the present invention depicted in FIG. 2 provides precision alignment of first apparatus A21 with second apparatus A22, so that axes of power inductor 21 and power inductor 22 are lined up. The method by which first apparatus A21 is aligned with second apparatus A22 follows a similar procedure to that of the alignment system depicted in FIG. 1. An alternating signal voltage is fed to I/O terminal T20 of magnetic loop antenna L21. The resulting alternating current in magnetic loop antenna L21 produces a time varying magnetic field in the surrounding region. The time varying magnetic field induces an emf at I/O terminals T21 of first RX loop antenna R21 and at I/O terminals T22 of second RX loop antenna R22. For a defined lateral XY alignment of first RX loop antenna R21 relative to magnetic loop antenna L21, there is a net zero magnetic flux intersecting the plane of first RX loop antenna R21. In this case, no emf is induced at I/O terminal T21 of first RX loop antenna R21. Similarly, there is a single lateral XY offset of second RX loop antenna R22 relative to magnetic loop antenna L21 where there is a net zero magnetic flux intersecting the plane of second RX loop antenna R22. In this case also, no emf is induced at I/O terminal T22 of second RX loop antenna R22.

Thus, precision alignment of first apparatus A21 with second apparatus A22 is accomplished when a null in the respective induced emf at I/O terminal T21 of first RX loop antenna R21 and I/O terminal T22 of second RX loop antenna R22 is detected. As before, the precision of the alignment increases when an axial Z offset of second apparatus A22 relative to first apparatus A21 is decreased. Thus highly precise alignment of power inductor 21 with of power inductor 22 can be achieved when their respective magnetic cores 27, 28 are in close proximity.

When precise alignment of power inductor 21 with power inductor 22 is achieved, highly efficient transfer of electrical power from power inductor 21 to power inductor 22 can be initiated. Alternatively, transfer of electrical power from power inductor 22 to power inductor 21 can be initiated.

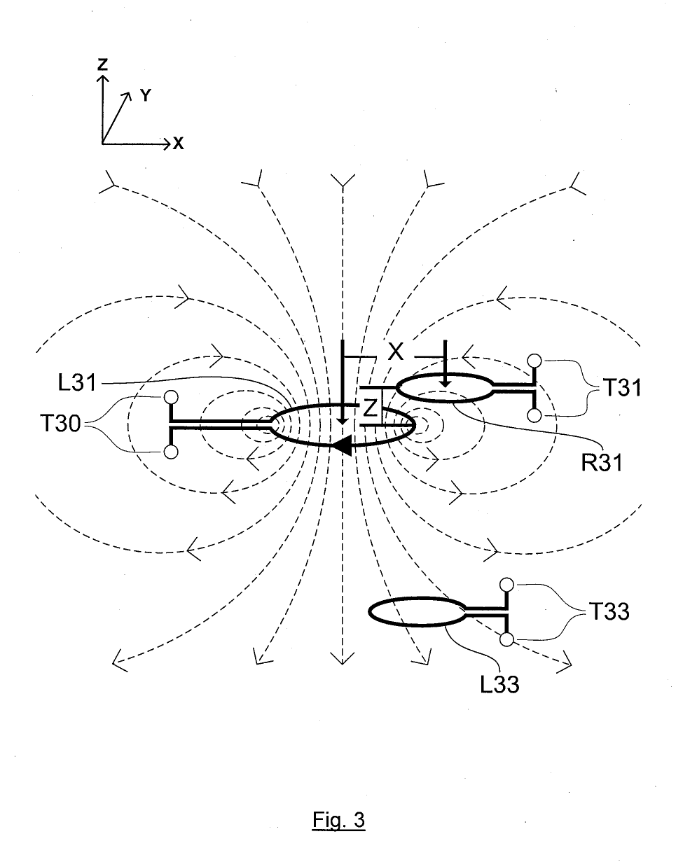

FIG. 3 shows a system comprising magnetic loop antenna L31 and first RX loop antenna R31. There is a lateral X offset of the centre of first RX loop antenna R31 relative to the centre of magnetic loop antenna L31 and an axial Z offset of the plane of first RX loop antenna R31 relative to the plane of magnetic loop antenna L31.

Magnetic loop antenna L31 has in input terminal T30, across which a voltage is applied producing a current which flows in the direction indicated by the arrow. The current flowing in magnetic loop antenna L31 generates a magnetic field. The direction of the magnetic field at the centre of the loop antenna L31 is given by the right hand grip rule. The magnetic field lines generated in the area around magnetic loop antenna L31 and their directions are represented by the dotted lines in FIG. 3. If the voltage applied to input terminal T30 is an alternating signal, the magnetic field lines around magnetic loop antenna L31 will also alternate. Typically, the alternating magnetic field will produce an alternating magnetic flux in the plane of any nearby loop antenna such as loop antenna L32 located near magnetic loop antenna L31. The alternating magnetic flux intersecting the plane of nearby loop antenna L32 induces an emf at the terminals T32 of nearby loop antenna L32. In FIG. 3, first RX loop antenna R31 overlaps with magnetic loop antenna L31, in such a way that the Z components of a portion of the magnetic field lines which intersect the plane of first RX loop antenna R31 point in one direction and Z components of the other portion point in the opposite direction. At a specific unique lateral X offset of first RX loop antenna R31 relative to magnetic loop antenna L31, the total net magnetic flux intersecting the plane of first RX loop antenna R31 is zero. In this case, no emf can be induced across terminal T31 of first RX loop antenna, even if the voltage applied to input terminal T30 or the current flowing in magnetic loop antenna L31 is alternating.

An alignment system can be provided based on the position of first RX loop antenna R31 relative to magnetic loop antenna L31 by adjusting the lateral X offset of first RX loop antenna R31 until a null is seen in the induced emf at terminal T31. In particular, the sharpness of the null in the induced emf at terminal T31 of first RX loop antenna R31 increases as the axial offset Z of first RX loop antenna R31 relative to magnetic loop antenna L31 decreases. The system is therefore operable to provide increased precision of alignment as the axial offset Z of first RX loop antenna R31 relative to magnetic loop antenna L31 decreases.

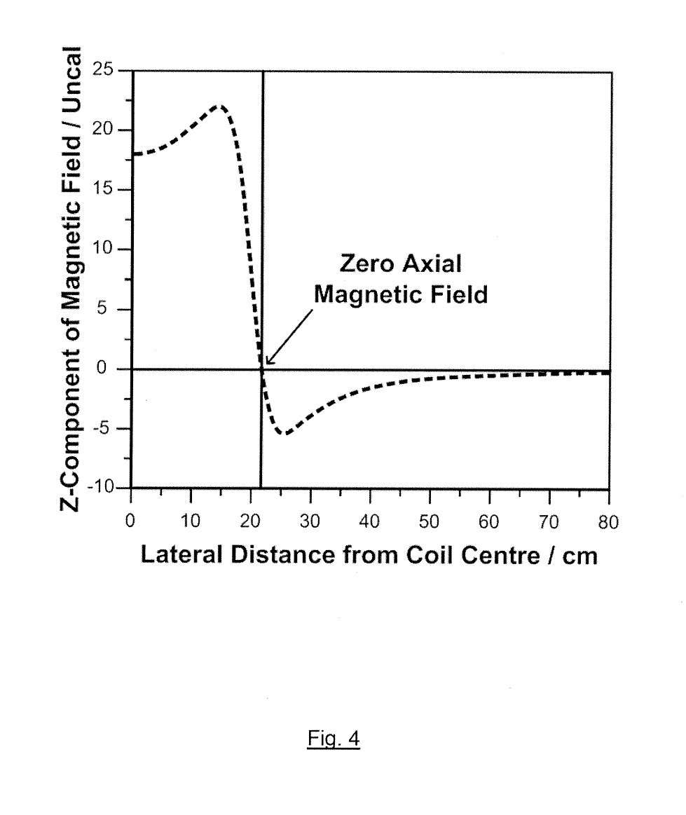

FIG. 4 shows a plot of the magnetic field strength surrounding a circular magnetic loop antenna, which is positioned so that the plane of the antenna is in the XY plane. The plot of FIG. 4 shows the Z component of the magnetic field strength as a function of lateral XY distance from the centre of the circular magnetic loop antenna. The radius of the loop antenna is 20 cm and it carries an alternating current with a peak value of 1 amp and with a frequency of 6 MHz. The units on the vertical axis of the plot of FIG. 4 are not calibrated; a scaling factor applies for each different propagating medium due to variations in the electrical conductivity and/or the magnetic permeability thereof. For the plot of FIG. 4, a constant axial Z distance of 4 cm above the circular loop antenna is maintained. The plot of FIG. 4 would correspond to the magnetic field strength at the centre of first RX loop antenna R31 of FIG. 3 for an axial Z distance of 4 cm, plotted as first RX loop antenna R31 is moved in the lateral X direction away from magnetic loop antenna L31 and starting from a position where both antennas are co-axial. It can be seen in FIG. 4 that the axial Z component of the magnetic field strength is positive for values of the lateral XY distance which are less than the loop radius, falls to zero just outside the loop at a lateral XY distance of 21.65 cm, and then decreases to a negative value as the lateral XY distance increases beyond 21.65 cm.

The sharp transition from a negative value at a lateral XY distance slightly less than 21.65 cm, to a positive value at a lateral XY distance slightly greater than 21.65 cm is the mechanism which provides for precise alignment according to the present invention. Similarly, the gradual fall off in the magnitude of the magnetic field strength as the lateral XY distance is increased beyond 25 cm is the mechanism which provides a gradual lead in of the alignment system of the present invention. Both features: gradual lead in, and precise identification of the alignment position are key requirements for a precision alignment system and for an alignment system that is required to operate autonomously—such as in an underwater environment.

In particular, for an automated alignment system, such as that which would be employed in an AUV, the gradual fall-off in the magnitude of the induced electrical signal with increasing distance provides a mechanism for guiding the second apparatus to the first apparatus from a starting position of gross misalignment.

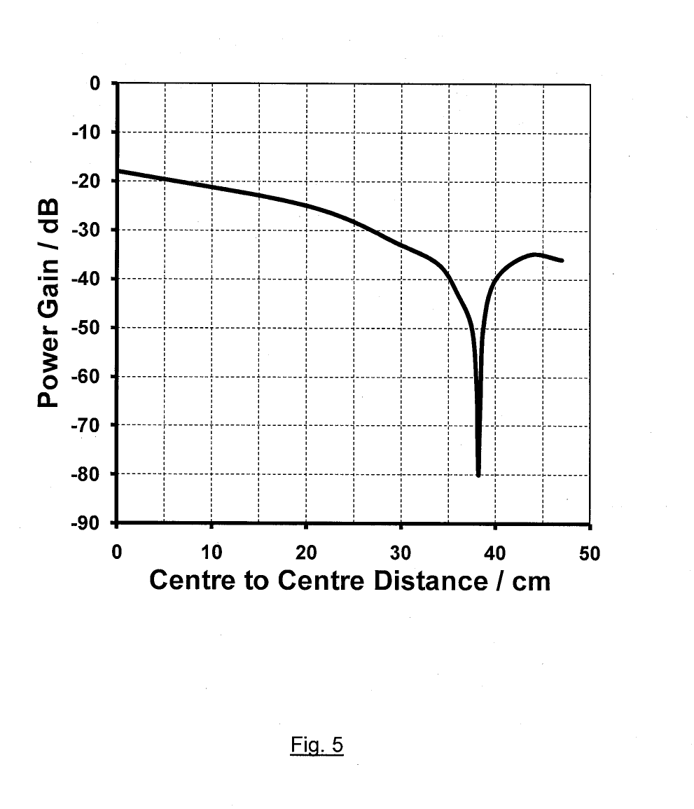

FIG. 5 shows a plot of the experimentally measured power transferred between a pair of identical magnetic loop antennas, as the centre to centre distance of the two antennas is increased and where the planes of both loop antennas are parallel. Each loop antenna has a radius of 20 cm. The plot begins with a centre to centre distance of zero, corresponding to the case where both loop antennas fully overlap. It can be seen that for a centre to centre distance of 38 cm, the power transferred from one antenna to the other falls to zero. FIG. 5 illustrates a principle of operation of the present invention: i.e. that for a system where an alternating electrical signal is fed to a magnetic loop antenna, an emf is induced in a nearby RX loop antenna. Furthermore, there exists a unique offset of the RX loop antenna where the induced emf falls rapidly to zero thereby providing a means for precise alignment of a first apparatus comprising the magnetic loop antenna and a second apparatus comprising the RX loop antenna. The sharpness of the null in the induced signal in the RX loop antenna can provide millimeter precision of the alignment system.

A further benefit of the alignment system depicted in FIG. 1 is that angular misalignment of first apparatus A11 and second apparatus A12 can be determined by comparison of the sharpness of the measured null at I/O terminal T11, and I/O terminal T12. The respective sharpness of the measured null at I/O terminal T11, and I/O terminal T12 decreases as the respective axial Z distance of first RX loop antenna R11 and second RX loop antenna R12 to magnetic loop antenna L11 increases.

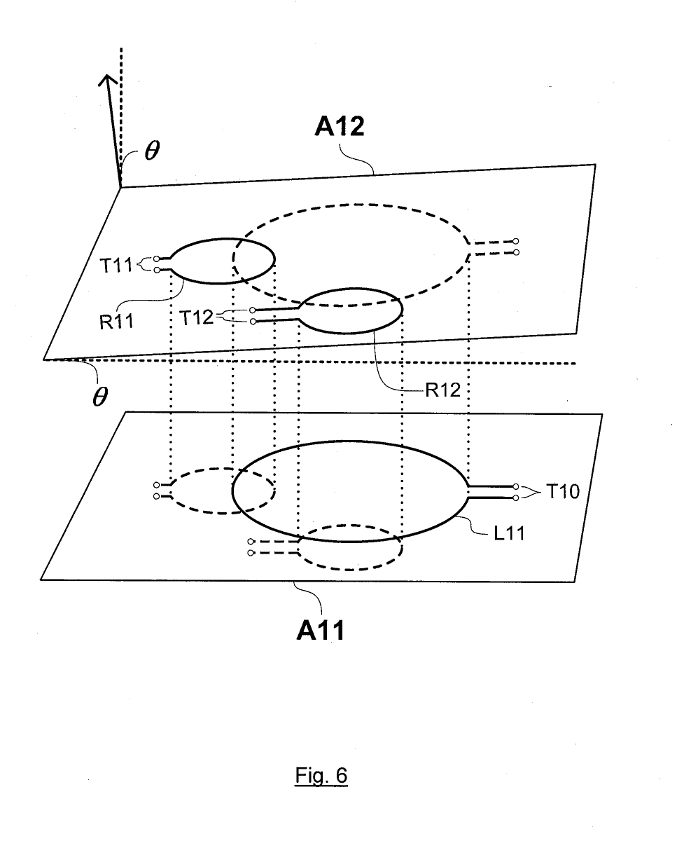

FIG. 6 shows the alignment system of the first embodiment of the present invention depicted in FIG. 1, where an angular misalignment of second apparatus A12 relative to first apparatus A11 has been introduced. The numerals used to identify the features of FIG. 6 are the same as those of FIG. 1. The angular misalignment is illustrated by the angle 8 in FIG. 6. As the angle 8 is increased, the Z distance of second RX loop antenna R12 to magnetic loop antenna L11 increases at a faster rate than the Z distance of first RX loop antenna R11 to magnetic loop antenna L11.

Thus, a difference in the respective sharpness of the measured null at I/O terminal T11, and I/O terminal T12 indicates that the axial displacement of first RX loop antenna R11 from magnetic loop antenna L11 is different to the axial displacement of second RX loop antenna R12 from magnetic loop antenna L11.

In another embodiment (not illustrated), first apparatus A11 of FIG. 1 and second apparatus A12 of FIG. 1 each further comprise a respective secondary antenna. When second apparatus A12 is optimally aligned with first apparatus A11 according to the procedure described for the embodiment of the present invention depicted in FIG. 1, the secondary antenna of the second apparatus A12 is precisely aligned for maximum coupling with the secondary antenna of first apparatus A11. This arrangement provides an optimum configuration of the secondary antenna of first apparatus A11 with the secondary antenna of second apparatus A12 for high speed wireless transfer of data from first apparatus A11 to second apparatus A12, and/or vice versa.

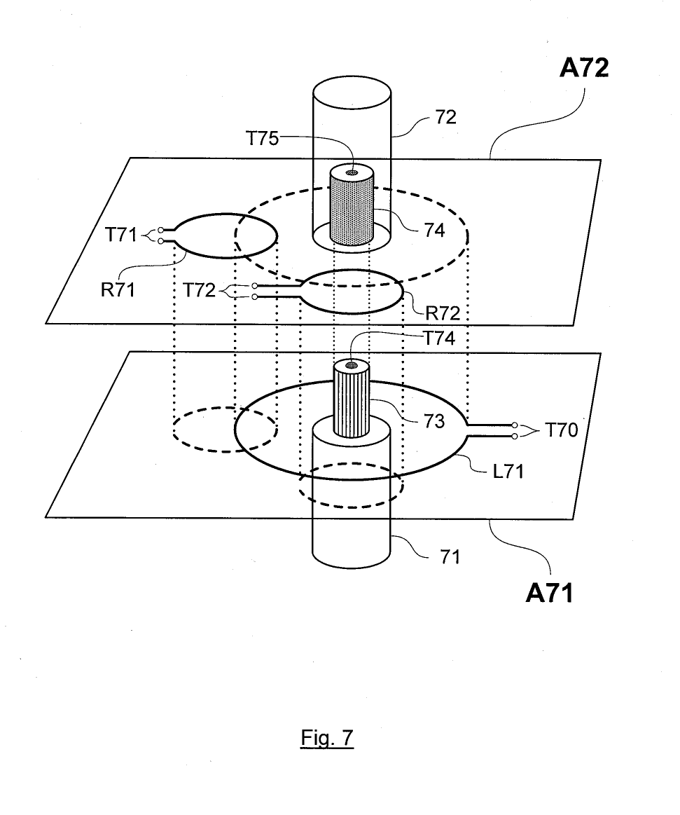

FIG. 7 shows a diagram illustrating an alignment system according to a third embodiment of the present invention. The alignment system comprises first apparatus A71 and second apparatus A72. First apparatus A71 comprises magnetic loop antenna L71 with an I/O terminal T70, and further comprises first interface unit 71 comprising mechanical interface 73 and electrical connection terminal T74. Second apparatus A72 comprises first RX loop antenna R71 and second RX loop antenna R72 where first RX loop antenna R71 comprises I/O terminal T71 and second RX loop antenna R72 similarly comprises I/O terminal T72. Second apparatus A72 further comprises second interface unit 72 which comprises mechanical interface 74 and electrical connection terminal T75.

During use, the alignment system of the third embodiment of the present invention depicted in FIG. 7 provides precision alignment of first apparatus A71 with second apparatus A72, so mechanical interface 73 can fit inside mechanical interface 74. The method by which first apparatus A71 is aligned with second apparatus A72 follows a similar procedure to that of the alignment system of FIG. 1. An alternating signal voltage is fed to I/O terminal T70 of magnetic loop antenna L71, the resulting alternating current in magnetic loop antenna L71 produces a time varying magnetic field in the surrounding region. The time varying magnetic field induces an emf at I/O terminals T71 of first RX loop antenna R71 and at I/O terminals T72 of second RX loop antenna R72. There is a single unique offset of first RX loop antenna R71 relative to magnetic loop antenna L71 where there is a net zero magnetic flux intersecting the plane of first RX loop antenna R71. In this case, no emf is induced at I/O terminal T71 of first RX loop antenna R71. Similarly, there is a single unique offset of second RX loop antenna R72 relative to magnetic loop antenna L71 where there is a net zero magnetic flux intersecting the plane of second RX loop antenna R72. In this case, no emf is induced at I/O terminal T72 of second RX loop antenna R72. When both of these conditions are met second apparatus A72 is aligned with first apparatus A71, so mechanical interface 73 can mate with mechanical interface 74.

When mechanical interface 73 is properly mated with mechanical interface 74, electrical connection terminal T74 makes contact with electrical connection terminal T75 thereby facilitating the transfer of power between interface unit 71 and interface unit 72 or vice versa. Similarly, high speed data transfer is possible when electrical connection terminal T74 makes contact with electrical connection terminal T75. Power and data transfer can take place simultaneously.

In each case, a means to switch on electrical power or to activate data transfer may be incorporated in first apparatus A71, or second apparatus A72 to avoid power loss through the conductive seawater prior to the mating of mechanical interface 73 with mechanical interface 74.

The mating of mechanical interface 73 with mechanical interface 74 may also be used to provide a mechanism for the transfer of mechanical power from first apparatus A71 to second apparatus A72 and vice versa.

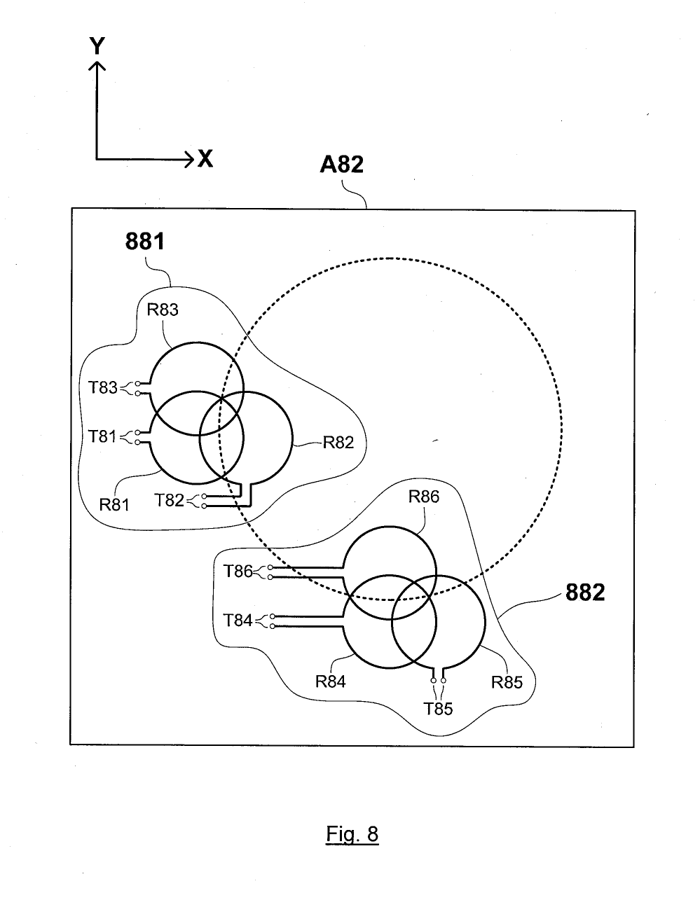

FIG. 8 shows a diagram illustrating a precision alignment system according to a fourth embodiment of the present invention. The alignment system comprises first apparatus (not shown) and second apparatus A82. First apparatus comprises a magnetic loop antenna (not shown). The projection of the magnetic loop antenna on second apparatus A82 is represented by the dotted circle in FIG. 8. Second apparatus A82 comprises a first antenna group 881 and second antenna group 882. First antenna group 881 comprises first RX loop antenna R81 comprising I/O terminal T81, second RX loop antenna L82 comprising I/O terminal T82 and third RX loop antenna L83 comprising I/O terminal T83. Second antenna group 882 comprises fourth RX loop antenna R84 comprising I/O terminal T84, fifth RX loop antenna R85 comprising I/O terminal T85 and sixth RX loop antenna R86 comprising I/O terminal T86. For this particular embodiment, all of loop antennas R81, R82, R83, R84, R85 and R86 are circular. Nonetheless, the present invention is by no means limited to embodiments comprising circular loop antennas.

The alignment system of a fourth embodiment of the present invention depicted in FIG. 8 provides a means to determine the necessary fine adjustment of second apparatus A82 when it is approximately aligned with first apparatus.

In FIG. 8, second RX loop antenna R82 is displaced from first RX loop antenna R81 in the X direction and third RX loop antenna R83 is displaced from first RX loop antenna R81 in the Y direction. Similarly, fifth RX loop antenna R85 is displaced from fourth RX loop antenna R84 in the X direction and sixth RX loop antenna R86 is displaced from fourth RX loop antenna R84 in the Y direction. First antenna group 881 is offset from the centre of magnetic loop antenna (represented by the circular dotted line) in the X direction; similarly, second antenna group 882 is offset from the centre of magnetic loop antenna in the Y direction.

During use, an alternating current flows in the magnetic loop antenna (not shown) producing a time varying magnetic field in the region surrounding magnetic loop antenna. This time varying magnetic field induces an emf at respective I/O terminals T81, T82 and T83 of first antenna group 881. Similarly, an emf is induced at respective I/O terminals T84, T85 and T86 of second antenna group 882. As second apparatus A82 is brought into alignment with the first apparatus the magnitude of the respective emf induced at terminals T81, T82, T83, T84, T85 and T86 varies. Nulls are recorded in the magnitude of the emf induced at one of terminals T81, T82, T83, and one of terminals T84, T85 and T86 when second apparatus A82 is approximately aligned with the first apparatus. The differences in the emf induced at respective terminals T81, T82, T83, T84, T85 and T86 when second apparatus A82 is approximately aligned with the first apparatus provides a means to determine the required fine adjustment of the position of second apparatus A82 in order to achieve precise alignment thereof.

For example, when a null in the magnitude of the induced emf is measured at terminal T82 of second RX loop antenna R82, a positive X adjustment of the position of second apparatus is required to provide improved alignment. Similarly, when a null in the magnitude of the induced emf is measured at terminal T86 of sixth RX loop antenna R86, a positive Y adjustment of the position of second apparatus is required. In some cases, a rotation of second apparatus about an axis through first antenna group 881 (not shown) or about an axis through second antenna group 882 (not shown) may be the correct adjustment.

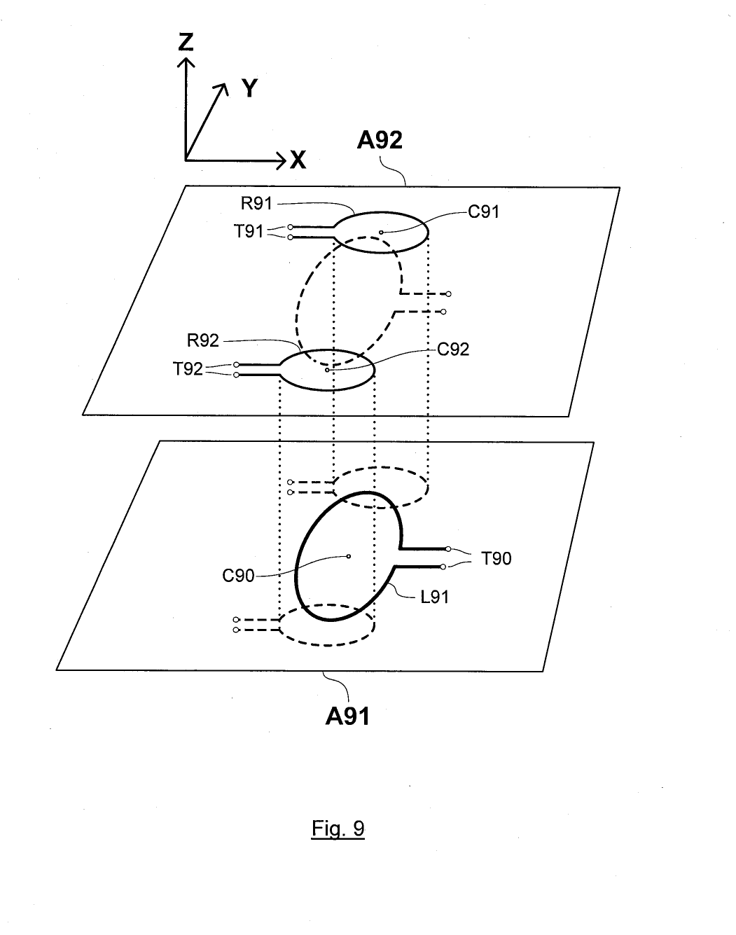

FIG. 9 shows a diagram illustrating a precision alignment system according to a fifth embodiment of the present invention. The alignment system of FIG. 9 comprises first apparatus A91, and second apparatus A92. First apparatus comprises a magnetic loop antenna L91 and first I/O terminal T90. Second apparatus A12 comprises first RX loop antenna R91, second RX loop antenna R92 second I/O terminal T92 and third I/O terminal T93. A local co-ordinate system is shown in the top left-hand portion of FIG. 9. Magnetic loop antenna L91, has an extended dimension in the Y-direction and a reduced dimension in the X-direction. First RX loop antenna R91 and second RX loop antenna R92 are both circular.

In FIG. 9, the lateral XY positions of first and second RX loop antennas R91 and R92 relative to magnetic loop antenna L11 are shown by dotted lines projected on a plane of first apparatus A91. Similarly, the lateral XY position of magnetic loop antenna L91 relative to first and second RX loop antennas R91 and R92 is shown as a dotted line projected on a plane of second apparatus A92. In FIG. 9, centre point C91 of first RX loop antenna R91 is offset in a positive Y direction relative to centre point C90 of magnetic loop antenna L91; similarly, centre point C92 of second RX loop antenna R92 is offset in a negative Y direction relative to centre point C90 of magnetic loop antenna L91.

During use, an alternating signal voltage is fed to I/O terminal T90 of magnetic loop antenna L91. The alternating voltage across I/O terminal T90 produces a time varying magnetic field in the region surrounding magnetic loop antenna L91. This time varying magnetic field induces an electromotive force (emf) at I/O terminals T91 of first RX loop antenna R91 and at I/O terminals T92 of second RX loop antenna R92. As second apparatus A92 is brought near first apparatus A91 from a starting position of gross misalignment the magnitude of the induced emf at I/O terminals T91 and T92 increases from zero. At a particular position and rotational alignment of second apparatus A92 relative to first apparatus A91, the magnitude of the induced emf at I/O terminals T91 and T92 falls rapidly to zero. Thus the alignment system embodying the present invention depicted in FIG. 9 provides a mechanism for the gradual lead in of second apparatus A92 relative to first apparatus A91 starting from a position of gross misalignment and a mechanism for the precise alignment of second apparatus A92 relative to first apparatus A91.

The precision alignment systems described herein are generally applicable to underwater environments. The specific feature of the embodiments of the present invention which lends itself to underwater applications is the use of loop antennas which produce magnetic fields in their immediate vicinity. However, there is no reason why the alignment systems described herein would be limited to underwater applications. In fact, the magnetic effects are more easily detected when the surrounding medium is some other non-conducting medium.

Moreover, the above descriptions of the specific embodiments are made by way of example only and are not for the purposes of limitation. It will be obvious to a person skilled in the art that in order to achieve some or most of the advantages of the present invention, practical implementations may not necessarily be exactly as exemplified and may include variations within the scope of the present invention.

What is claimed is:

1. A precision alignment system comprising a first apparatus and a second apparatus, said first apparatus comprising a magnetic loop antenna, said second apparatus comprising at least a first RX antenna
wherein, during use, an input electrical signal is fed to said magnetic loop antenna, said input electrical signal inducing a first induced electrical signal in said first RX antenna, said first induced signal providing a measurement of the alignment of said second apparatus to said first apparatus
and wherein a precise alignment of said second apparatus relative to said first apparatus is defined as the position of said second apparatus when the magnitude of said first induced signal in said first RX antenna has a local minimum value.

2. A precision alignment system according to claim 1 wherein said second apparatus further comprises a second RX antenna and wherein during use said input electrical signal in said magnetic loop antenna induces a second induced electrical signal in said second RX antenna.

3. A precision alignment system according to claim 2 wherein the magnitude of said first induced signal in said first RX antenna and said second induced signal in said second RX antenna each has a local minimum value when said second apparatus is precisely aligned to said first apparatus.

4. A precision alignment system according to claim 1 wherein said first RX antenna is a loop antenna.

5. A precision alignment system according to claim 1 wherein said precise alignment of said second apparatus relative to said first apparatus brings a defined point on said second apparatus into alignment with the centre of said magnetic loop antenna of said first apparatus.

6. A precision alignment system according to claim 1 wherein said precise alignment of said second apparatus relative to said first apparatus defines an axial Z position of said second apparatus relative to said first apparatus.

7. A precision alignment system according to claim 1 wherein said magnetic loop antenna comprises at least one winding of electrically conductive wire.

8. A precision alignment system according to claim 1 wherein lateral XY dimensions of said magnetic loop antenna are greater than an axial Z dimension thereof.

9. A precision alignment system according to claim 4 wherein said first RX loop antenna comprises at least one winding of electrically conductive wire.

10. A precision alignment system according to claim 4 wherein said first RX loop antenna has lateral XY dimensions which are greater than an axial Z dimension thereof.

11. A precision alignment system according to claim-1 wherein said first RX antenna is a solenoid having an axial Z dimension which is greater than lateral XY dimensions thereof.

12. A precision alignment system according to claim 4 wherein lateral XY dimensions of said magnetic loop antenna are greater than lateral XY dimensions of said first RX loop antenna.

13. A precision alignment system according to any of claim 4 wherein said magnetic loop antenna and said first RX loop antenna are both circular loop antennas.

14. A precision alignment system according to claim 13 wherein the radius of said magnetic loop antenna is equal to that of said first RX loop antenna and wherein said local minimum of said first induced signal in said first RX loop antenna occurs when a centre to centre distance of said magnetic loop antenna and said first RX loop antenna is given by the following relationship
D=1.52×R
where R is the radius of each said loop antennas and D is said centre to centre distance.
$$\frac{{V}_{2} {V}_{1}}{( {V}_{2} - {V}_{1} )} Δ t = s$$

15. A precision alignment system according to claim 1 wherein said first apparatus further comprises a primary inductive unit, and wherein said second apparatus comprises a secondary inductive unit.

16. A precision alignment system according to claim 15 wherein said first and second inductive units are mutually aligned when said second apparatus is precisely aligned with said first apparatus.

17. A precision alignment system according to claim 15 wherein said second apparatus is operable to send and/or receive electrical power wirelessly to and/or from said first apparatus via said primary and said secondary inductive units.

18. A precision alignment system according to claim 1 wherein said second apparatus further comprises a secondary antenna and is operable to send and/or receive a data stream wirelessly to and/or from said first apparatus via said secondary antenna of said second apparatus.

19. A precision alignment system according to claim 1 wherein said first apparatus further comprises a secondary antenna and were said second apparatus is operable to send and/or receive a data stream wirelessly to and/or from said first apparatus via said secondary antenna of said first apparatus and said secondary antenna of said second apparatus.

20. A precision alignment system according to claim 1 further comprising a plurality of loop antennas located in the vicinity of said first RX antenna, wherein induced signals in one or more of said plurality of loop antennas provide an indication of a fine adjustment to the position of said second apparatus required to achieve precise alignment of said second apparatus relative to said first apparatus.

21. A precision alignment system according to claim 1 wherein said second apparatus is a mobile underwater unit.

22. A precision alignment system according to claim 1 wherein said first apparatus is a fixed underwater installation.

23. A precision alignment system according to claim 1 wherein said first apparatus further comprises a first connector having a first profile and wherein said second apparatus comprises a second connector having a second profile, said second profile being the inverse of said first profile so that said first and second connectors mechanically fit together
wherein said first and second connectors are aligned when said second apparatus is aligned according to the system of the present invention.

24. A precision alignment method comprising the steps of transmitting an electromagnetic signal via a magnetic loop antenna of a first apparatus, receiving said transmitted electromagnetic signal as a first induced electrical signal in a first RX antenna of a second apparatus, determining the magnitude of said first induced electrical signal, adjusting the position of said second apparatus, monitoring the change in said first induced electrical signal and achieving alignment of said second apparatus relative to said first apparatus when the magnitude of said first induced electrical signal falls to zero.

25. A precision alignment method according to claim 24 wherein said transmitted electromagnetic signal is also received as a second induced signal in a second RX antenna of said second apparatus, where the change in said second induced electrical signal is also monitored on adjustment of the position of said second apparatus and wherein alignment of said second apparatus relative to said first apparatus is achieved when the magnitude of each said first induced electrical signal and said second induced electrical signal falls to zero.

26. A precision alignment method according to claim 24 wherein said first RX antenna of said first apparatus comprises a at least three loop antennas, and wherein a correction to the position of said second apparatus relative to said first apparatus to achieve alignment of said second apparatus is determined from induced signals in each said at least three loop antennas.
